(19) United States
(12) Patent Application Publication
(10) Pub. No.: US 2026/0322361 A1
(43) Pub. Date: Oct. 15, 2026

(54) RELAXATION OSCILLATOR AND METHOD FOR GENERATING OSCILLATION SIGNAL IN RELAXATION OSCILLATOR

(71) Applicant: Realtek Semiconductor Corp., HsinChu (TW)

(72) Inventor: Yu-Hsien Li, HsinChu (TW)

(73) Assignee: Realtek Semiconductor Corp., HsinChu (TW)

(21) Appl. No.: 19/646,597

(22) Filed: Apr. 14, 2026

Related U.S. Application Data
(60) Provisional application No. 63/788,766, filed on Apr. 14, 2025.

(30) Foreign Application Priority Data
Mar. 25, 2026 (TW) 115111487

(51) Int. Cl. H03K 3/03; H03K 3/014

(52) U.S. Cl. CPC H03K 3/03; H03K 3/014

(57) ABSTRACT

A relaxation oscillator and a method for generating at least one oscillation signal in the relaxation oscillator are provided. The relaxation oscillator includes a capacitor, a resistor, an inverting amplifier and a first logic inverter, where a first terminal of the resistor is coupled to a first terminal of the capacitor. The inverting amplifier is configured to generate a first digital signal according to an analog signal on the first terminal of the capacitor, and the first logic inverter is configured to generate a second digital signal according to the first digital signal, where a second terminal of the resistor is configured to pull up or pull down the analog signal according to the first digital signal, and a second terminal of the capacitor is configured to receive the second digital signal.

### CROSS REFERENCE TO RELATED APPLICATIONS

This application claims the benefit of U.S. Provisional Application No. 63/788,766, filed on Apr. 14th, 2025. The content of the application is incorporated herein by reference.

### BACKGROUND OF THE INVENTION

### 1. FIELD OF THE INVENTION

The present invention is related to oscillator designs, and more particularly, to a relaxation oscillator and a method for generating at least one oscillation signal in the relaxation oscillator.

### 2. DESCRIPTION OF THE PRIOR ART

With the increasing popularity of smart devices, the market demand for wireless sensing devices (e.g. wearable electronic devices) is growing. Power consumption and chip area are crucial considerations for these devices. In an electronic system, an oscillator is an important building block, where different types of oscillators have different advantages and disadvantages. For example, a crystal oscillator has lower phase noise and better frequency stability, but also has a longer startup time and higher power consumption, and the required external crystal components lead to higher manufacturing costs, making it difficult to meet the requirements of wearable electronic devices. Ring oscillators can obtain good power efficiency, but their performance is quite sensitive to variations in process, voltage, and temperature. In comparison, a relaxation oscillator can achieve better frequency stability, frequency tuning function and figure of merit (FOM), and is therefore more suitable to be applied in wireless sensing devices.

Relaxation oscillators still have some disadvantages, however. For example, a relaxation oscillator architecture according to the related art needs to use a continuous-time comparator and a common-mode feedback circuit. These blocks typically require a large number of transistors, thereby introducing additional flicker noise and thermal noise. Although high-frequency components of the noise can be suppressed by a low-pass filter, reducing noise at low frequencies is difficult, such that the relaxation oscillator of the related art is unsuitable for wearable electronic devices which are mainly used for sensing low-frequency signals.

Thus, there is a need for a novel relaxation oscillator architecture and an associated method, which simplifies the circuit complexity (e.g. the number of transistors), thereby solving the problems of the related art.

### SUMMARY OF THE INVENTION

An objective of the present invention is to provide a relaxation oscillator and a method for generating at least one oscillation signal in the relaxation oscillator, in order to meet the requirements of oscillators in wearable electronic devices.

At least one embodiment of the present invention provides a relaxation oscillator. The relaxation oscillator comprises a capacitor, a resistor, an inverting amplifier and a first logic inverter, where a first terminal of the resistor is coupled to a first terminal of the capacitor. The inverting amplifier is configured to generate a first digital signal according to an analog signal on the first terminal of the capacitor, and the first logic inverter is configured to generate a second digital signal according to the first digital signal, where a second terminal of the resistor is configured to pull up or pull down the analog signal according to the first digital signal, and a second terminal of the capacitor is configured to receive the second digital signal.

At least one embodiment of the present invention provides a method for generating at least one oscillation signal in a relaxation oscillator. The method comprises: utilizing an inverting amplifier of the relaxation oscillator to generate a first digital signal according to an analog signal on a first terminal of a capacitor of the relaxation oscillator; utilizing a first logic inverter to generate a second digital signal according to the first digital signal; utilizing a second terminal of the capacitor to receive the second digital signal; and utilizing a resistor of the relaxation oscillator to pull up or pull down the analog signal according to the first digital signal.

The relaxation oscillator and the associated method provided by the embodiments of the present invention can utilize a resistor, a capacitor and simple logic gates to form the relaxation oscillator. In comparison with the relaxation oscillator of the related art, the number of transistors used in the architecture of the present invention can be significantly reduced, which not only significantly reduces the overall circuit area, but also avoids introducing additional flicker noise and thermal noise as much as possible. Thus, the present invention can implement an oscillator meeting the requirements of the wearable electronic devices without introducing any side effect or in a way that is less likely to bring side effects.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a relaxation oscillator according to an embodiment of the present invention.

FIG. 2 is a diagram illustrating signals involved in the relaxation oscillator shown in FIG. 1 according to an embodiment of the present invention.

FIG. 3 is a diagram illustrating a condition where a threshold voltage of a logic inverter in the relaxation oscillator shown in FIG. 1 is higher than an ideal level according to an embodiment of the present invention.

FIG. 4 is a diagram illustrating a condition where the threshold voltage of the logic inverter in the relaxation oscillator shown in FIG. 1 is lower than the ideal level according to an embodiment of the present invention.

FIG. 5 is a diagram illustrating a workflow of a method for generating at least one oscillation signal in a relaxation oscillator according to an embodiment of the present invention.

### DETAILED DESCRIPTION

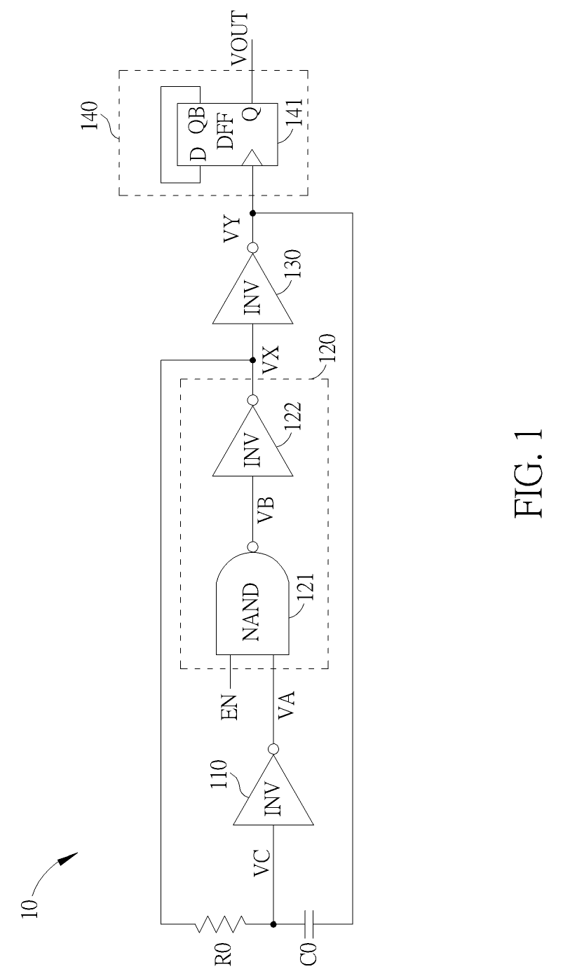

FIG. 1 is a diagram illustrating a relaxation oscillator 10 according to an embodiment of the present invention. In this embodiment, the relaxation oscillator 10 comprises a capacitor C0, a resistor R0, an inverting amplifier, and a first logic inverter such as an inverter 130 (labeled “INV” in FIG. 1 for brevity), where the inverting amplifier may be a second logic inverter such as an inverter 110 (labeled “INV” in FIG. 1 for brevity). As shown in FIG. 1, a first terminal of the resistor R0 (e.g. a lower terminal of the resistor R0 shown in FIG. 1) is coupled to a first terminal of the capacitor C0 (e.g. an upper terminal of the capacitor C0 shown in FIG. 1). In this embodiment, the inverting amplifier 110 is configured to generate a first digital signal such as a signal VA according to an analog signal such as a signal VC on the first terminal of the capacitor C0, and the inverter 130 is configured to generate a second digital signal such as a signal VY according to the signal VA, where a second terminal of the resistor R0 (e.g. an upper terminal of the resistor R0 shown in FIG. 1) is configured to pull up or pull down the signal VC according to the signal VA, and a second terminal of the capacitor C0 (e.g. a lower terminal of the capacitor C0 shown in FIG. 1) is configured to receive the signal VY.

As shown in FIG. 1, the relaxation oscillator 10 may further comprise a frequency divider 140, where the frequency divider 140 is coupled to the inverter 130, and is configured to perform frequency division on the signal VY to generate an oscillation output signal such as a signal VOUT. In this embodiment, the frequency divider 140 may comprise a flip-flop such as a D-type flip-flop (DFF) 141, where a clock terminal of the DFF 141 is coupled to an output terminal of the inverter 130, a data input terminal of the DFF 141 (e.g. a terminal labeled “D” on the DFF 141 shown in FIG. 1) is coupled to an inverted data output terminal of the DFF 141 (e.g. a terminal labeled “QB” on the DFF 141 shown in FIG. 1), and a data output terminal of the DFF 141 (e.g. a terminal labeled “Q” on the DFF 141 shown in FIG. 1) is configured to output the signal VOUT.

In addition, the relaxation oscillator 10 may further comprise an AND gate 120, where the AND gate 120 is configured to generate a third digital signal such as a signal VX according to an enable signal EN and the signal VA, where the second terminal of the resistor R0 receives the signal VX. In this embodiment, the AND gate 120 may comprise a NAND gate 121 and an inverter 122, where the NAND gate 121 may perform a NAND logic operation on the enable signal EN and the signal VA to generate a signal VB, and the inverter 122 may generate the signal VX according to the signal VB.

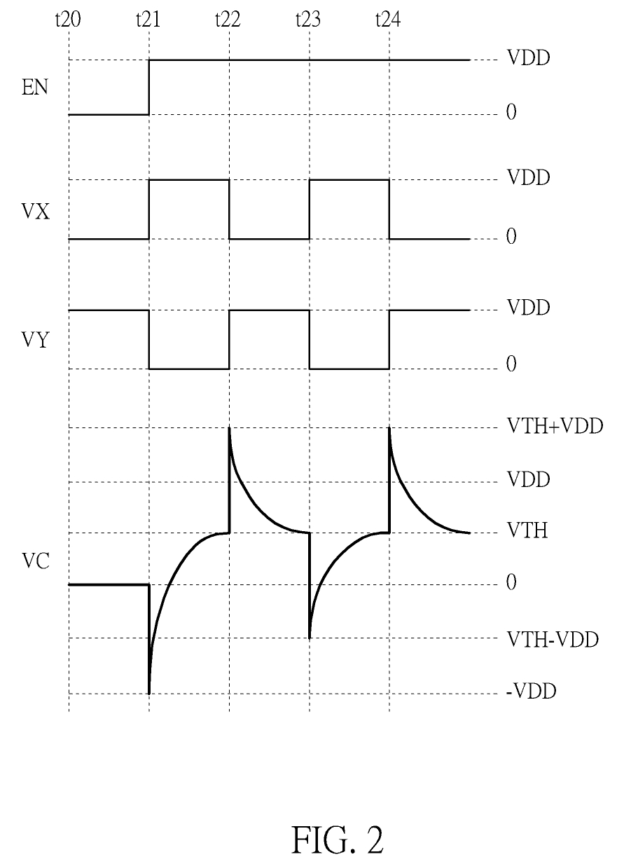

FIG. 2 is a diagram illustrating signals such as EN, VX, VY, and VC involved in the relaxation oscillator 10 shown in FIG. 1 according to an embodiment of the present invention. In a disable phase (e.g. a phase between time points t20 and t21), the signal EN is set to a first reference level such as a ground level (which can be regarded as a logic value “0”), the signal VX is fixed at the ground level, the signal VY is fixed at a second reference level such as a power supply level (which can be regarded as a logic value “1”), and the signal VC is fixed at the ground level. In a startup phase (e.g. a phase between time points t21 and t22), the signal EN is set to the power supply level, the signal VX is pulled to the power supply level, the signal VY is pulled to the ground level, and the signal VC is pulled up from the ground level minus a reference level difference to a threshold VTH of the inverter 110, where the reference level difference is equal to the power supply level minus the ground level. In a pull-down phase (e.g. a phase between time points t22 and t23), the signal VA is pulled to the ground level in response to the signal VC being higher than the threshold VTH, the signal VX is pulled to the ground level, the signal VY is pulled to the power supply level, and the signal VC is pulled down from the threshold VTH plus the reference level difference to the threshold VTH. In a pull-up phase (e.g. a phase between time points t23 and t24), the signal VA is pulled to the power supply level in response to the signal VC being lower than the threshold VTH, the signal VX is pulled to the power supply level, the signal VY is pulled to the ground level, and the signal VC is pulled up from the threshold VTH minus the reference level difference to the threshold VTH.

In this embodiment, the ground level may be 0, and the power supply level may be VDD, where the reference level difference may be VDD - 0 = VDD. Specifically, the signal EN may be set to 0 to make the relaxation oscillator 10 operate in the disable phase, and the signals VX, VY, and VC of the relaxation oscillator 10 are therefore initialized to 0, VDD, and 0, respectively. At the time point t21, the signal EN may be pulled from 0 to VDD to make the relaxation oscillator 10 enter the startup phase from the disable phase, where the AND gate 120 may pull the signal VX (corresponding to the second terminal of the resistor R0) from 0 to VDD in response to the signal EN, and the inverter 130 may pull the signal VY (corresponding to the second terminal of the capacitor C0) from VDD to 0 in response to the signal VX. Thus, the signal VC on the first terminal of the capacitor C0 may be pulled from 0 to -VDD at the time point t21 in response to the second terminal of the capacitor C0 being pulled from VDD to 0, where the signal VC may start to be pulled up from -VDD at the time point t21 in response to the signal VX on the second terminal of the resistor R0 being pulled to VDD.

At the time point t22, the inverter 110 may pull down the signal VA to 0 in response to the signal VC being pulled up to the threshold VTH, to make the relaxation oscillator 10 enter the pull-down phase from the startup phase. The AND gate 120 may pull down the signal VX (corresponding to the second terminal of the resistor R0) from VDD to 0 in response to the signal VA, and the inverter 130 may pull the signal VY (corresponding to the second terminal of the capacitor C0) from 0 to VDD in response to the signal VX. Thus, the signal VC on the first terminal of the capacitor C0 may be pulled from VTH to (VTH+VDD) at the time point t22 in response to the second terminal of the capacitor C0 being pulled from 0 to VDD, where the signal VC may start to be pulled down from (VTH+VDD) at the time point t22 in response to the signal VX on the second terminal of the resistor R0 being pulled to 0.

At the time point t23, the inverter 110 may pull up the signal VA to VDD in response to the signal VC being pulled down to the threshold VTH, to make the relaxation oscillator 10 enter the pull-up phase from the pull-down phase,. The AND gate 120 may pull up the signal VX (corresponding to the second terminal of the resistor R0) from 0 to VDD in response to the signal VA, and the inverter 130 may pull the signal VY (corresponding to the second terminal of the capacitor C0) from VDD to 0 in response to the signal VX. Thus, the signal VC on the first terminal of the capacitor C0 may be pulled from VTH to (VTH-VDD) at the time point t22 in response to the second terminal of the capacitor C0 being pulled from VDD to 0. The signal VC may start to be pulled up from (VTH-VDD) at the time point t23 in response to the signal VX on the second terminal of the resistor R0 being pulled to VDD. Then, the relaxation oscillator 10 may repeatedly perform the operations of the pull-down phase from the time point t22 to t23 and the operations of the pull-up phase from the time point t23 to t24.

It should be noted that, when the threshold voltage VTH of the inverter 110 is at an ideal level (e.g. 0.5×VDD), a duty cycle of the signals VX and VY may be 50% (i.e. the length of time at the first reference level is equal to the length of time at the second reference level). Under this condition, the signals VX and VY may serve as the oscillation output signal of the relaxation oscillator 10. Under some conditions, the threshold voltage VTH of the inverter 110 may be higher than the ideal level (i.e. VTH > 0.5×VDD) due to process variations. Under some conditions, the threshold voltage VTH of the inverter 110 may be lower than the ideal level (i.e. VTH < 0.5×VDD) due to process variations.

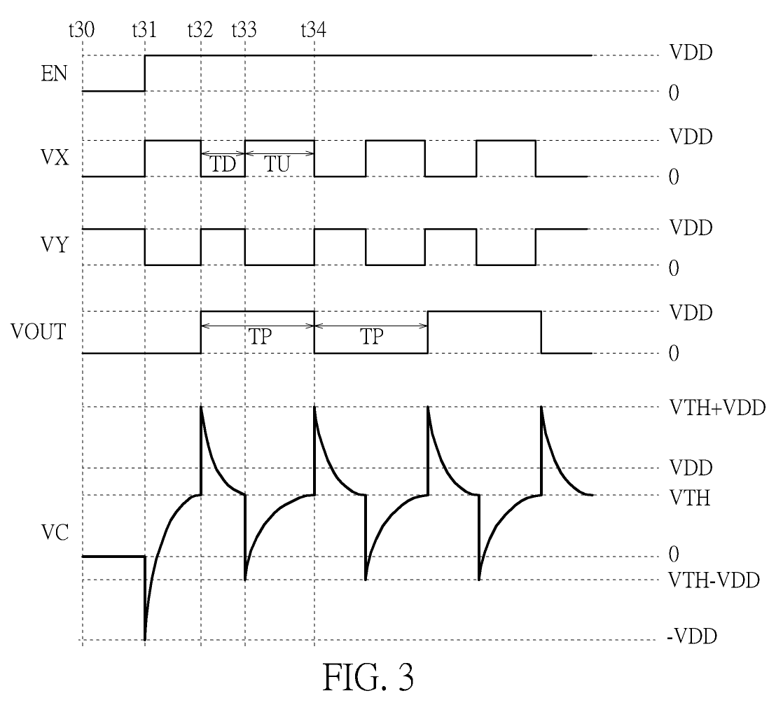

FIG. 3 is a diagram illustrating a condition where the threshold voltage VTH of the inverter 110 in the relaxation oscillator 10 shown in FIG. 1 is higher than the ideal level (e.g. the threshold voltage VTH of the inverter 110 is VTH1 > 0.5×VDD) according to an embodiment of the present invention, where the operations at time points t30 and t31 in the embodiment of FIG. 3 are the same as the operations at time points t20 and t21 in the embodiment of FIG. 2, and related details are not repeated here for brevity. In comparison with the time point t22 in the embodiment of FIG. 2, the inverter 110 in the embodiment of FIG. 3 may pull down the signal VA to 0 in response to the signal VC being pulled up to a threshold VTH1 at a time point t32, to make the signal VX be pulled down from VDD to 0 and the signal VY be pulled up from 0 to VDD. The signal VC on the first terminal of the capacitor C0 may be pulled from VTH1 to (VTH1+VDD) at the time point t32, and the signal VC may start to be pulled down from (VTH1+VDD) at the time point t32. Furthermore, in comparison with the time point t23 in the embodiment of FIG. 2, the inverter 110 in the embodiment of FIG. 3 may pull up the signal VA to VDD in response to the signal VC being pulled down to the threshold VTH1 at a time point t33, to make the signal VX be pulled up from 0 to VDD and the signal VY be pulled down from VDD to 0. The signal VC on the first terminal of the capacitor C0 may be pulled from VTH1 to (VTH1-VDD) at the time point t33, and the signal VC may start to be pulled up from (VTH1-VDD) at the time point t33. It should be noted that a voltage difference between the first terminal and the second terminal of the resistor R0 is VTH1 + VDD - 0 = VTH1 + VDD at the time point t32, and the voltage difference between the first terminal and the second terminal of the resistor R0 is VTH1 - VDD - VDD = VTH1 - (2×VDD) at the time point t33. When VTH1 > 0.5×VDD, |VTH1 + VDD| > |VTH1 - (2×VDD)|, such that a speed of the signal VC being pulled down from the time point t32 to t33 may be greater than a speed of the signal VC being pulled up from the time point t33 to t34, and therefore a time difference TD between the time points t32 and t33 (corresponding to a length of time that the signal VX is at 0) may be less than a time difference TU between the time points t33 and t34 (corresponding to a length of time that the signal VX is at VDD), making the duty cycle of the signals VX and VY be not equal to 50%. This duty cycle problem can be solved by the frequency divider 140. More particularly, a length of time that the signal VOUT generated by the frequency divider 140 performing frequency division on the signal VY is at VDD and a length of time that the signal VOUT is at 0 are both equal to a time difference between the time points t32 and t34 (as indicated by TP).

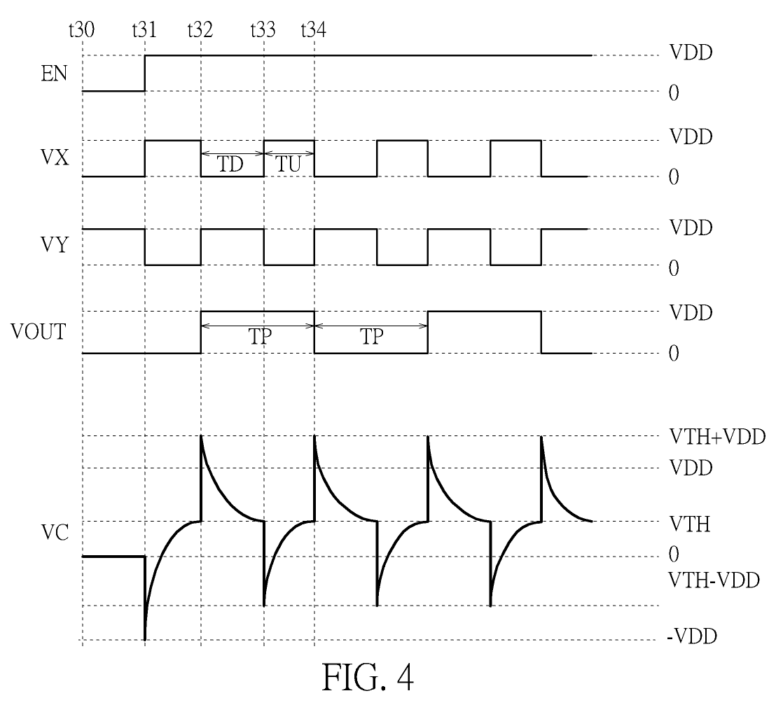

FIG. 4 is a diagram illustrating a condition where the threshold voltage VTH of the inverter 110 in the relaxation oscillator 10 shown in FIG. 1 is lower than the ideal level (e.g. the threshold voltage VTH of the inverter 110 is VTH2 < 0.5×VDD) according to an embodiment of the present invention, where the operations at time points t40 and t41 in the embodiment of FIG. 4 are the same as the operations at time points t20 and t21 in the embodiment of FIG. 2; related details are not repeated here for brevity. In comparison with the time point t22 in the embodiment of FIG. 2, the inverter 110 in the embodiment of FIG. 4 may pull down the signal VA to 0 in response to the signal VC being pulled up to a threshold VTH2 at a time point t42, to make the signal VX be pulled down from VDD to 0 and the signal VY be pulled up from 0 to VDD. The signal VC on the first terminal of the capacitor C0 may be pulled from VTH2 to (VTH2+VDD) at the time point t42, and the signal VC may start to be pulled down from (VTH2+VDD) at the time point t42. Furthermore, in comparison with the time point t23 in the embodiment of FIG. 2, the inverter 110 in the embodiment of FIG. 4 may pull up the signal VA to VDD in response to the signal VC being pulled down to the threshold VTH2 at a time point t43, to make the signal VX be pulled up from 0 to VDD and the signal VY be pulled down from VDD to 0. The signal VC on the first terminal of the capacitor C0 may be pulled from VTH2 to (VTH2-VDD) at the time point t43, and the signal VC may start to be pulled up from (VTH2-VDD) at the time point t43. It should be noted that a voltage difference between the first terminal and the second terminal of the resistor R0 is VTH2 + VDD - 0 = VTH2 + VDD at the time point t42, and the voltage difference between the first terminal and the second terminal of the resistor R0 is VTH2 - VDD - VDD = VTH2 - (2×VDD) at the time point t43. When VTH2 < 0.5×VDD, |VTH2 + VDD| < |VTH2 - (2×VDD)|, such that a speed at which the signal VC is pulled down from the time point t42 to t43 may be less than a speed at which the signal VC is pulled up from the time point t43 to t44, and therefore a time difference TD between the time points t42 and t43 (corresponding to a length of time that the signal VX is 0) may be greater than a time difference TU between the time points t43 and t44 (corresponding to a length of time that the signal VX is VDD), making the duty cycle of the signals VX and VY be not equal to 50%. This duty cycle problem can be solved by the frequency divider 140. More particularly, a length of time that the signal VOUT generated by the frequency divider 140 performing frequency division on the signal VY is at VDD and a length of time that the signal VOUT is at 0 are both equal to a time difference between the time points t42 and t44 (as indicated by TP).

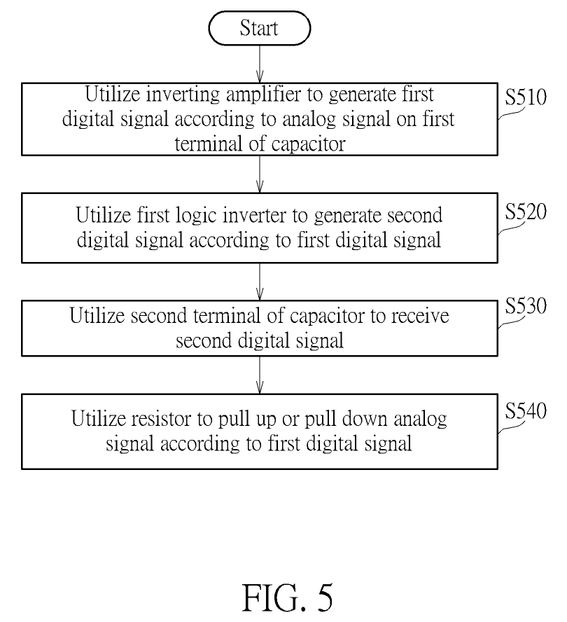

FIG. 5 is a diagram illustrating a workflow of a method for generating at least one oscillation signal (e.g. the signals VX, VY, and VOUT) in a relaxation oscillator (e.g. the relaxation oscillator 10 shown in FIG. 1) according to an embodiment of the present invention. It should be noted that the workflow shown in FIG. 5 is for illustrative purposes only, and is not meant to be a limitation to the present invention. For example, one or more steps may be added, deleted or modified in the workflow shown in FIG. 5. In addition, if a same result can be obtained, these steps do not have to be executed in the exact order shown in FIG. 5.

In Step S510, the relaxation oscillator may utilize an inverting amplifier (e.g. the inverter 110 shown in FIG. 1) to generate a first digital signal (e.g. the signal VA shown in FIG. 1) according to an analog signal (e.g. the signal VC shown in FIG. 1) on a first terminal of a capacitor (e.g. the capacitor C0 shown in FIG. 1) of the relaxation oscillator.

In Step S520, the relaxation oscillator may utilize a first logic inverter (e.g. the inverter 130 shown in FIG. 1) to generate a second digital signal (e.g. the signal VY shown in FIG. 1) according to the first digital signal.

In Step S530, the relaxation oscillator may utilize a second terminal of the capacitor to receive the second digital signal.

In Step S540, the relaxation oscillator may utilize a resistor (e.g. the resistor R0 shown in FIG. 1) to pull up or pull down the analog signal according to the first digital signal.

In summary, the architecture and associated method provided by the embodiments of the present invention can utilize a resistor, a capacitor, and simple logic gates to form a relaxation oscillator. The architecture of the present invention does not need to use an operational amplifier or a common-mode feedback circuit, so that an overall number of transistors can be greatly reduced, thereby avoiding introducing additional flicker noise and thermal noise. Furthermore, the embodiments of the present invention will not significantly increase additional costs. Thus, the present invention can implement an oscillator suitable for wearable electronic devices without introducing any side effect or in a way that is less likely to introduce side effects.

The foregoing outlines the features of several embodiments, enabling those skilled in the art to fully appreciate the aspects of the present disclosure. Those skilled in the art should recognize that the present disclosure provides a foundation for designing or modifying other processes and structures to achieve substantially the same functions and/or substantially the same results as those of the embodiments introduced herein. Furthermore, such equivalent arrangements do not deviate from the spirit and scope of the present disclosure, and various changes, substitutions, and alterations may be made without so departing.

What is claimed is:

1. A relaxation oscillator, comprising:
a capacitor;
a resistor, wherein a first terminal of the resistor is coupled to a first terminal of the capacitor;
an inverting amplifier, configured to generate a first digital signal according to an analog signal on the first terminal of the capacitor; and
a first logic inverter, configured to generate a second digital signal according to the first digital signal;
wherein a second terminal of the resistor is configured to pull up or pull down the analog signal according to the first digital signal, and a second terminal of the capacitor is configured to receive the second digital signal.

2. The relaxation oscillator of claim 1, wherein the inverting amplifier is a second logic inverter.

3. The relaxation oscillator of claim 1, further comprising:
a frequency divider, coupled to the first logic inverter, configured to perform frequency division on the second digital signal to generate an oscillation output signal.

4. The relaxation oscillator of claim 3, wherein the frequency divider comprises:
a flip-flop, wherein a clock terminal of the flip-flop is coupled to an output terminal of the first logic inverter, a data input terminal of the flip-flop is coupled to an inverted data output terminal of the flip-flop, and a data output terminal of the flip-flop is configured to output the oscillation output signal.

5. The relaxation oscillator of claim 1, further comprising:
an AND gate, configured to generate a third digital signal according to an enable signal and the first digital signal, wherein the second terminal of the resistor receives the third digital signal.

6. The relaxation oscillator of claim 5, wherein:
in a disable phase, the enable signal is set to a first reference level, the third digital signal is fixed at the first reference level, the second digital signal is fixed at a second reference level, and the analog signal is fixed at the first reference level;
in a startup phase, the enable signal is set to the second reference level, the third digital signal is pulled to the second reference level, the second digital signal is pulled to the first reference level, and the analog signal is pulled up from the first reference level minus a reference level difference to a threshold of the inverting amplifier, wherein the reference level difference is equal to the second reference level minus the first reference level;
in a pull-down phase, the first digital signal is pulled to the first reference level in response to the analog signal being higher than the threshold, the third digital signal is pulled to the first reference level, the second digital signal is pulled to the second reference level, and the analog signal is pulled down from the threshold plus the reference level difference to the threshold; and
in a pull-up phase, the first digital signal is pulled to the second reference level in response to the analog signal being lower than the threshold, the third digital signal is pulled to the second reference level, the second digital signal is pulled to the first reference level, and the analog signal is pulled up from the threshold minus the reference level difference to the threshold.

7. A method for generating at least one oscillation signal in a relaxation oscillator, comprising:
utilizing an inverting amplifier of the relaxation oscillator to generate a first digital signal according to an analog signal on a first terminal of a capacitor of the relaxation oscillator;
utilizing a first logic inverter to generate a second digital signal according to the first digital signal;
utilizing a second terminal of the capacitor to receive the second digital signal; and
utilizing a resistor of the relaxation oscillator to pull up or pull down the analog signal according to the first digital signal.

8. The method of claim 7, wherein the inverting amplifier is a second logic inverter.

9. The method of claim 7, further comprising:
utilizing a frequency divider of the relaxation oscillator to perform frequency division on the second digital signal to generate an oscillation output signal.

10. The method of claim 9, wherein the frequency divider comprises a flip-flop, a clock terminal of the flip-flop is coupled to an output terminal of the first logic inverter, a data input terminal of the flip-flop is coupled to an inverted data output terminal of the flip-flop, and utilizing the frequency divider of the relaxation oscillator to perform the frequency division on the second digital signal to generate the oscillation output signal comprises:
utilizing a data output terminal of the flip-flop to output the oscillation output signal.

11. The method of claim 7, further comprising:
utilizing an AND gate of the relaxation oscillator to generate a third digital signal according to an enable signal and the first digital signal, wherein the second terminal of the resistor receives the third digital signal.

12. The method of claim 11, wherein utilizing the resistor of the relaxation oscillator to pull up or pull down the analog signal according to the first digital signal comprises:
in a disable phase, setting the enable signal to the first reference level, to make the third digital signal be fixed at the first reference level, make the second digital signal be fixed at the second reference level, and make the analog signal be fixed at the first reference level;
in a startup phase, setting the enable signal to the second reference level, to make the third digital signal be pulled to the second reference level, make the second digital signal be pulled to the first reference level, and make the analog signal be pulled up from the first reference level minus a reference level difference to a threshold of the inverting amplifier, wherein the reference level difference is equal to the second reference level minus the first reference level;
in a pull-down phase, pulling the first digital signal to the first reference level in response to the analog signal being higher than the threshold, to make the third digital signal be pulled to the first reference level, make the second digital signal be pulled to the second reference level, and make the analog signal be pulled down from the threshold plus the reference level difference to the threshold; and
in a pull-up phase, pulling the first digital signal to the second reference level in response to the analog signal being lower than the threshold, to make the third digital signal be pulled to the second reference level, make the second digital signal be pulled to the first reference level, and make the analog signal be pulled up from the threshold minus the reference level difference to the threshold.
